(19) United States
(12) Patent Application Publication
(10) Pub. No.: US 2007/0240758 A1
(43) Pub. Date: Oct. 18, 2007

(54) Double-sided solar module

(76) Inventor: Thomas Spartz, LaPorte, IN (US)

Correspondence Address: Lawrence J. Crain;GREER, BURNS & CRAIN, LTD.,, Suite 2500, 300 South Wacker Drive, Chicago, IL, 60606, US

(21) Appl. No.: 11/404,279

(22) Filed: Apr. 14, 2006

(51) Int. Cl. H01L 31/00

(52) U.S. Cl. 136/256

(57) ABSTRACT

A solar module for converting light into electric current includes a hollow body having a first opening for enabling light to enter the hollow body. The module further includes an inside wall and an outside wall, and at least one photoactive layer for absorbing light attached to each wall for absorbing light and converting it into electric current.

### FIELD OF INVENTION

The present invention relates generally to photovoltaic systems for converting light to electrical power, and more particularly to devices for increasing the efficiency and reliability of solar energy collection.

### BACKGROUND OF THE INVENTION

The predominant type of solar modules built today is silicon-based, oriented for maximum exposure to light, and effective only when the light source is not obstructed through shade, cloudy or dirty conditions, which reduce the average power output to typically only a few production hours per day in the more populated areas around the world. The intermittent power delivery of solar electricity is a primary drawback to widespread acceptance as a reliable source or part of an electrical grid transmission network. Another limitation is that any portion of a conventional solar module not facing the light source is wasted.

Yet another obstacle to the acceptance of solar energy is performance per square meter. Despite the many benefits of solar energy as a renewable distributed energy solution, when compared to other forms of electricity generation per kWh per square meter, solar energy is barely competitive. Using the comparable generation footprint of kWh per square meter, solar energy produces 0.1 kWh, wind generates 3 kWh, coal generates 500 kWh, and nuclear power generates 650 kWh per square meter. Without greater performance per square meter, solar technology will not become an economically viable factor for electricity generation.

It is an accepted fundamental of this field that 1000 watts per square meter of solar energy reaches the earth's surface. When solar cells are measured for efficiency, the percent (%) efficiency is based on the ratio of electron output compared to the 1000 watts per square meter standard. Thus, 10% efficiency means 100 watts of output in the field per square meter of solar cells. Traditionally, rigid flat semiconductor wafers have been used to make solar cells with 10-14% efficiency. Photovoltaic modules manufactured using glass as a substrate, a superstrate, or as both surfaces have a high weight per unit area and are very fragile. Although large solar collector modules can be desirable for corresponding greater electrical output, large modules are heavier, bulkier and more cumbersome.

New physically flexible, solution-processed thin-film photovoltaic (TFPV) materials can be printed like newspapers, spinning seamlessly from roll to roll. The resulting solar cells are easier to transport and deploy. However, the large area (footprint) required for producing sufficient power output from these materials limits applications requiring greater density per area. In practice, this has resulted in yields well below 40%, offsetting or negating any cost savings realized with this approach. Unfortunately, neither traditional silicon-based solar cells, nor today's flexible, printable TFPV solar cells are sufficiently efficient per square meter to be practical for large-scale power applications or footprint-sensitive applications.

Another method used to boost the amount of solar electrical power includes reflective or concentrating optics to produce increases of light by maximizing the amount of sunlight available to the solar cells. Another known type of solar module is a tubular module having light collectors facing inside the tube. This design requires reflectors to channel light inside the tube or reflect light back into the tube, and requires a light collector to face the light, either directly or reflected. These concentrator modules generate significant power output and are used for remote outer space applications, but are not considered practical or cost-effective for most terrestrial or consumer-based needs.

Existing photovoltaic solar modules are limited in performance compared to market needs. The generally planar (flat) arrays of solar modules are not flexible to location and must be oriented to face the source of light. Another limitation to known solar cells is that they absorb only visible light. These solar devices “see” less than half of the sun's power reaching the earth. The other half lies in the ultraviolet (UV) and infrared (IR) light spectra.

### SUMMARY OF THE INVENTION

To address these concerns, an improved solar energy collector is provided which significantly increases collection efficiency. By orienting the collector surfaces in back-to-back fashion, a greater amount of light is collected. More specifically, a solar module for converting light into electric current includes a hollow body having an opening for enabling light to enter the hollow body, an inside wall and an outside wall. At least one photoactive layer for absorbing light is attached to both the inside wall and the outside wall of the tubular body, and converts absorbed light into electric current.

### DESCRIPTION OF THE DRAWINGS

FIG. 1 is a perspective view of a solar module in accordance with one embodiment of the present module;

FIGS. 2-6 are perspective views of the solar module of FIG. 1, shown with various cross-sections of a tubular body;

FIGS. 7-12 are perspective views of a solar module in accordance with another embodiment of the present module;

FIG. 13 is a partial sectional view showing the arrangement of a thin film photovoltaic (TFPV) panel in the solar module in accordance with one embodiment of the present module;

FIG. 14 is an illustration of quantum dots used in fabricating a photoactive layer of the TFPV panels;

FIG. 15 is a partial sectional view showing the arrangement of the thin film photovoltaic (TFPV) panels in accordance with another embodiment of the present module;

FIG. 16 is a partial sectional view of a thin film photovoltaic (TFPV) panel having multiple photoactive layers in accordance with one embodiment of the present module;

FIG. 17 is a perspective view of the solar module of FIG. 1, provided with TFPV insert panels in accordance with another embodiment of the present module;

FIGS. 18 and 19 are perspective views of other configurations of the solar modules having TFPV insert panels;

FIG. 20 is a plan view of a solar unit including a plurality of solar modules in accordance with one embodiment of the module;

FIG. 21 is a bottom view of the solar unit of FIG. 20, showing a connection terminal for inverters; and

FIG. 22 is a bottom view of an alternate embodiment of the solar unit of FIG. 20, showing a battery connected to the inverters.

### DETAILED DESCRIPTION OF THE INVENTION

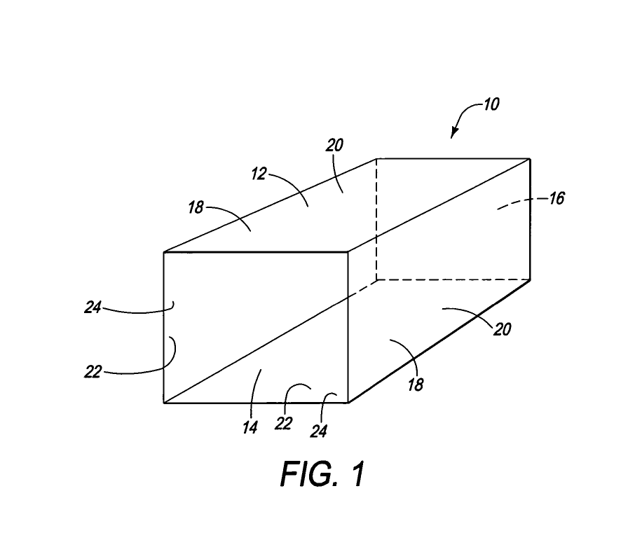

Turning now to FIG. 1, a solar module 10 in accordance with one embodiment of the present module includes a tubular body 12 and a pair of openings 14 and 16 at the opposite ends of the body. The two openings 14, 16 preferably have substantially the same dimensions, however variations are contemplated. An outside wall 18 of the body 12 is covered with a layer of thin film photovoltaic (TFPV) panel 20, which is oriented to have its light collecting surface facing out. Similarly, an inside wall 22 of the body 12 is also provided with a TFPV layer 24. The TFPV layers 20, 24 absorb visible, ultraviolet (UV) and infrared (IR) light from the sun or artificial light sources, and generates electric current.

Generally, the amount of electric current generated by the solar module 10 is dependent on the relationship between the lengths of the tubular body 12 and the width or area of the openings 14, 16. Deeper or longer length-to-opening ratios (e.g., 2 to 1) are less efficient per meter of TFPV panel 20 required, but generate more current output per square meter. Shallower or shorter length-to-opening ratios (e.g., 0.5 to 1) are more efficient per meter of TFPV panel 20 required, but generate less current output per square meter.

Therefore, the length-to-opening ratio will depend on the intended application of the solar module 10. For example, a greater length-to-opening ratio (i.e., greatest efficiency per square meter) would be used for outer space applications where the total power output per square meter (power capacity over the life of the satellite, etc.) is the goal. However, in an application where costs are a greater concern than the amount of solar collection per square meter, a smaller length-to-opening ratio is used to waste less TFPV panel. An example of this would be a solar-powered water pump.

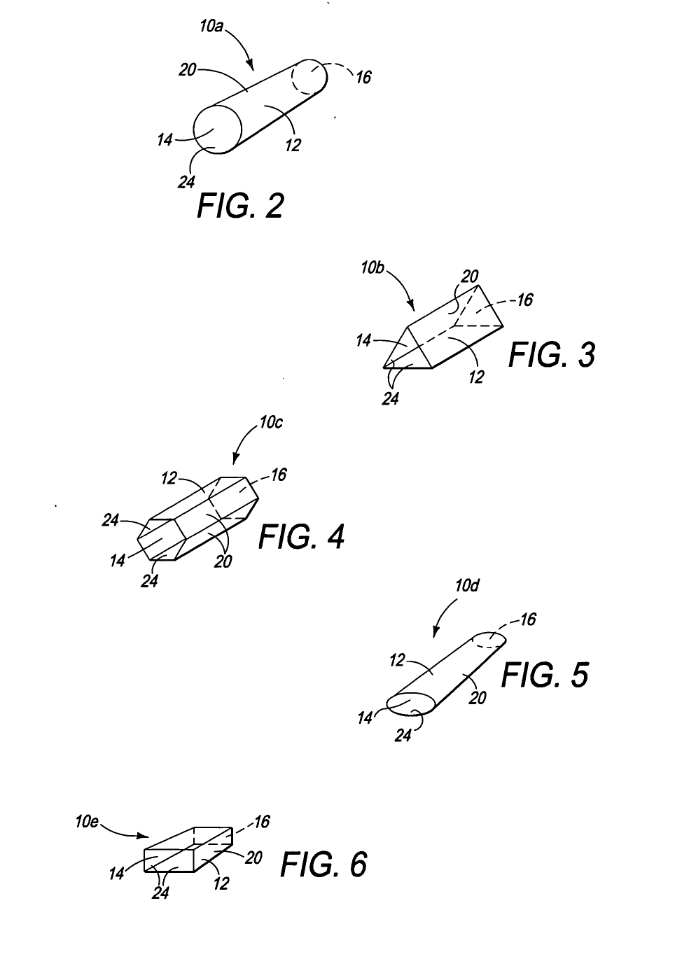

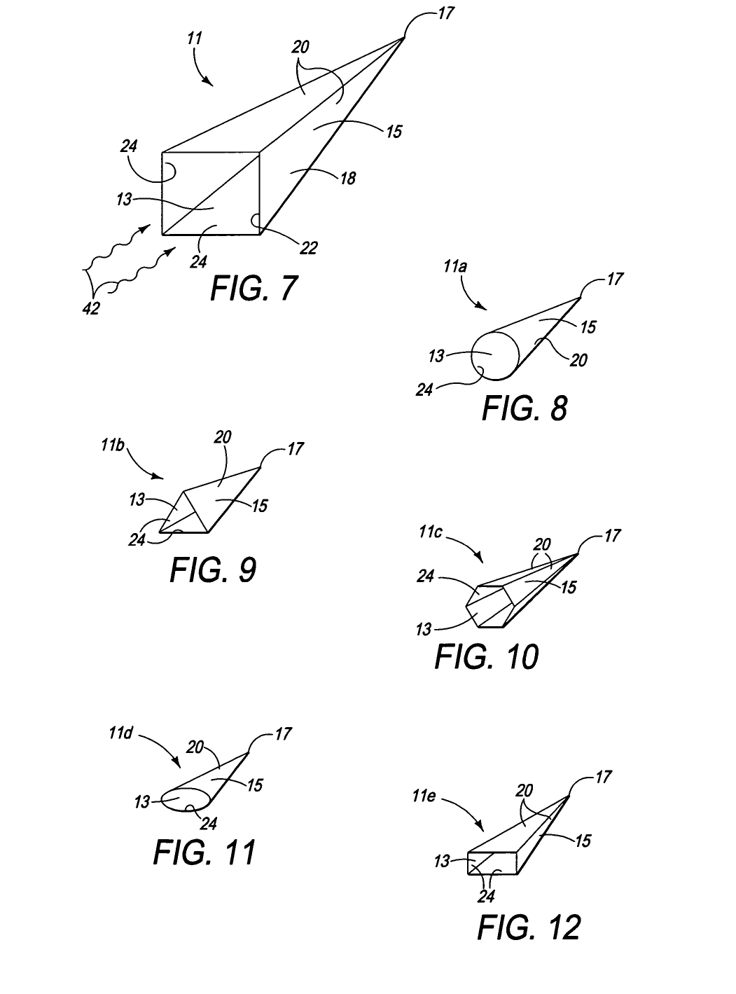

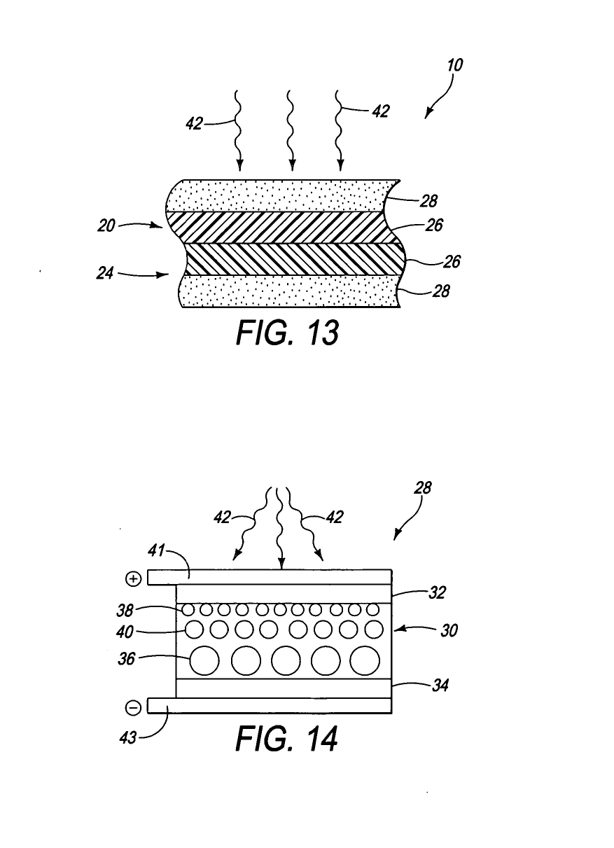

In the embodiment shown in FIG. 1, the cross-section of the tubular body 12 has a generally square shape. It should be understood, however, that the term “tube” or “tubular” is used herein to describe any structure having a pair of openings provided on the opposite ends of a hollow housing or enclosure which allow light to pass through its length. Accordingly, the cross-section of the tubular body 12 may have many other shapes such as, for example, circular, oval, triangular, hexagonal, rectangular or any other polygonal shapes. Some of these shapes are shown in FIGS. 2-6 as modules 10a-10e.

Turning now to FIG. 7, another embodiment of the present module includes a solar module 11 having a generally similar cross-section at an opening 13 of a body 15 as in the opening 14 of the solar module 10 shown in FIG. 1. However, the body 15 of the solar module 11 converges from the opening 13 to an enclosed point 17 at the opposite end, giving it a generally conical shape, rather than tubular. It should be understood that the term “conical” is used herein to describe any structure having an opening in a hollow housing or enclosure that converges from this opening to an enclosed end or point, which may be sharp or rounded. As such, the cross-section of the conical body 15 may have many other shapes such as, for example, circular, oval, triangular, hexagonal, rectangular or any other polygonal shapes, some of which are shown in FIGS. 8-12 as modules 11a-11e.

The conical body 15 also includes outside and inside walls, which are referenced with the same numerals 18 and 22 as with the tubular body 12. As in the embodiments shown in FIG. 1, the outside wall 18 of the conical body 15 is covered with a layer of the thin film photovoltaic (TFPV) panel 20, which is oriented to have its light collecting surface facing out. Similarly, the inside wall 22 of the body 15 is also provided with the TFPV layer 24. The TFPV layers 20, 24 absorb visible, ultraviolet (UV) and infrared (IR) light from the sun or artificial light sources, and generate electric current.

Generally, the amount of electric current generated by the solar module 11 is dependent on the relationship between the lengths of the conical body 15 and the width or area of the opening 13. Deeper or longer length-to-opening ratios (e.g., 2 to 1) are less efficient per meter of TFPV panel 20 required, but generate more current output per square meter. Shallower or shorter length-to-opening ratios (e.g., 0.5 to 1) are more efficient per meter of TFPV panel required, but generate less current output per square meter. Therefore, the length-to-opening ratio will depend on the intended application of the solar module 10 as in the embodiment of FIG. 1. For example, a greater length-to-opening ratio would be used for space applications, and a smaller length-to-opening ratio in a solar-powered water pump.

Turning now to FIG. 13, the TFPV panels 20 and 24 that are disposed respectively on the outside 18 and inside 22 walls of the tubular body 12 and the conical body 15, each includes a flexible polymer film substrate 26 and a photoactive layer 28. In one embodiment shown in FIG. 14, the photoactive layer 28 is formed using quantum dots 30, which, as known in the art, are nanocrystals in the quantum confined size range. The quantum dots 30 are sandwiched in an intrinsic region between a p-type region 32 and an n-type region 34 by sensitizing conjugated polymers with IR active quantum dots 36 to UV active quantum dots 38, including visible light active quantum dots 40 in between. The quantum dots 30 are provided in a polymer solution that is applied using a screen printer across a patterned surface. The surface is configured in the shape of small cubes or similar shapes to keep the quantum dots packed tightly together, in a confined pattern during the printing, UV curing and drying process. Multiple layers of the quantum dot polymer are applied using the same confined cube pattern and process, applying each new layer on top of the previous layer. In this manner, a spectrally tunable system for accessing the full light spectrum is obtained. In other words, the wavelength “tunability” afforded by quantum dots is used to derive photocurrent spectra tailored to several different regions of the IR to UV spectrum. The result is that the quantum dot polymer blends of the photoactive layer 28 convert electrons to electricity from the visible, plus the UV and IR spectrum, resulting in increased power output from similar sized traditional silicon-based solar cells. Another benefit of also utilizing the UV and IR spectra is that it reduces the intermittency of solar output produced by visible-only solar modules. From sunrise to sunset, the applied combination of UV, IR and the visible spectra will significantly outperform a visible light spectra-only solar module and support greater output and reliability to users.

In another embodiment of the present module, blended fullerenes may be employed in lieu of quantum dots in the photoactive layer 28 and blended into an ink and formed on the substrate 26 using a screen-printing method. However, other known methods such as ink-jet, spray, electrolytic or vapor deposition are also considered suitable.

The photoactive layer 28 also includes an electrically conductive layer 41 formed on the p-type region 32 and an electrically conductive layer 43 formed on the n-type region 34. The conductive layers 41 and 43 carry the current generated within the photoactive layer 28 to an electric lead line (not shown) respectively attached to each layer.

Alternatively, the photoactive layer 28 may also be formed using a p-type CdTe layer and an n-type CdS layer, or a copper indium gallium diselenide (CIGS) layer, as known in the art. The photoactive layer 28 of this embodiment is also formed on the substrate using a screen-printing method. However, other known printing methods such as roll-to-roll, ink-jet, spray, electrolytic or vapor deposition may also be used.

Returning now to FIG. 13, the substrate 26 of the outside TFPV panel 20 is directly adhered to the substrate 26 of the inside TFPV panel 24, thereby forming the outside and inside walls 18, 22. While chemical adhesive is preferred for attaching the substrates 26, any other suitable fastening technology is contemplated. In this manner, the assembly of substrates is sufficiently rigid to enable formation of the preferred tubular structure of the solar modules 10 and 11. It will be understood that in the present application discussion of the use or implementation of module 10 will also apply to alternate embodiments 10, 60 and the like. For example, one continuous sheet of combined TFPV panels 20, 24 may be folded at the four comers and the ends attached to form the square cross-sectioned module 10 shown in FIG. 1. As described above, the ends of the sheet may be attached together by adhesives or the like. The tubular or conical shape of the solar modules 10 and 11 may also be formed by attaching two or more sheets of the combined TFPV panels 20, 24. For example, four sheets each forming the four sides of cell modules 10 and 11 may be attached along common edges forming corners of the module.

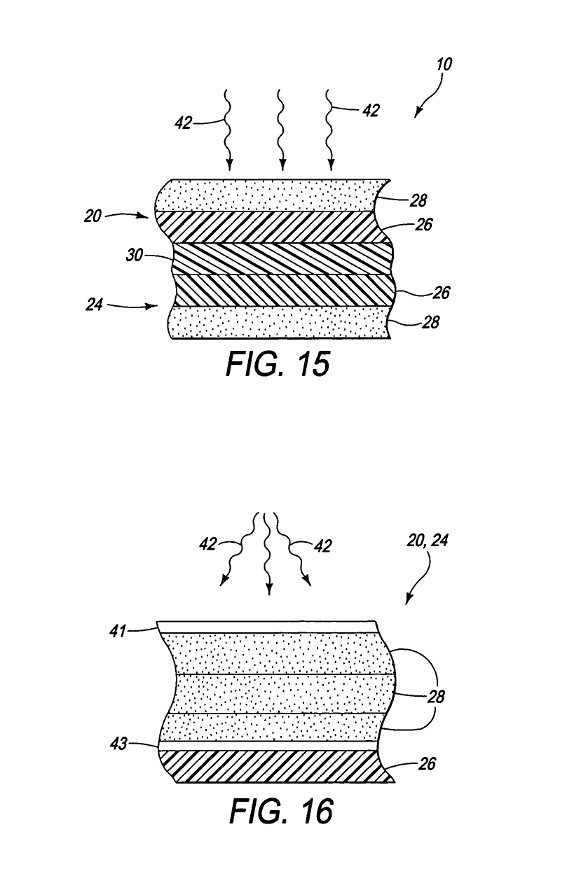

Turning now to FIG. 15, and in accordance with another embodiment of the present solar modules 10 and 11, the substrate 26 of the outside TFPV panel 20 is attached to one side (outside) of a frame 30 and that of the inside TFPV panel 24 is attached to an opposite side (inside) of the frame. The frame 30 may be any relatively rigid, lightweight material, such as plastic, which is formed in the tubular or conical shape of the desired solar modules 10 and 11. Attachment of the TFPV panels 20, 24 to the frame 30 maybe accomplished through adhesives or the like as described above.

To fabricate the solar module 10 or 11, the substrate 26 of the TFPV panel 20, provided in one ore more sheets, is attached to the outside of the frame 30 to substantially cover the outside surface area of the frame. Similarly, the substrate 26 of one or more sheets of the TFPV panel 24 is attached to the inside of the frame 30 to substantially cover the inside surface area of the frame. In this manner, the photoactive layer 28 of the inside TFPV panel 24 faces inwardly and the photoactive layer 28 of the outside TFPV panel 20 faces outwardly.

It will be appreciated that the back-to-back or the double-sided structure of the TFPV panels 20 and 24 is operable at any angle relative to the location of the light source 42 (see FIG. 7). Direct light source delivers substantially 100% of the efficiency inherent in the TFPV panels 20, 24, and shaded areas average approximately 70% efficiency. Since the TFPV panels 20 and 24 use the UV and IR spectra, and not just visible light, the present solar module 10 is not limited to direct sunlight or a preferred angle of the light source. The double-sided solar module 10 maximizes the amount of output per meter by using the shaded surfaces, even at 70% efficiency. When all the solar surfaces (i.e., the TFPV panels 20, 24) of an array of the double-sided solar modules 10 positioned in a square meter are added and that output is reduced by 30%, the result is still much more solar power per square meter than the output of conventional solar module.

The tubular and conical configurations of the present module 10 produce a three-dimensional effect, employing height plus the traditional planar length×width size to utilize more overall mass. The length-to-opening ratio can be as deep as 2 or 3 to 1, adding greater output per square meter even as the overall efficiency per solar cell is reduced due to the greater level of shading in the depths of the length of the tube. The result is that the tubular and conical output per square meter of the solar modules 10 and 11 is considerably higher in watts per square meter.

Referring to FIG. 16, in accordance with another embodiment of the present solar modules 10 and 11, each of the inside and outside TFPV layers 20, 24 includes the substrate 26, the conductive layer 43 formed on the substrate and multiple photoactive layers 28 (three shown in the Figure) formed on the conductive layer. The conductive layer 41 is formed on the surface of the top photoactive layer 28.

The photoactive layers 28 of this embodiment are also formed on the substrate using a screen-printing method. However, other known printing methods such as roll-to-roll, ink-jet, spray, electrolytic or vapor deposition may also be used. During the formation, depending on the choice of application method, each photoactive layer 28 is printed, dried and cured before the next layer is formed on top of the previous layer using the same process.

It should be understood that the photoactive layers 28 are transparent so the light 42 is able to penetrate and be absorbed by each layer. Absorption of light 42 by multiple photoactive layers 28 increases the total amount of electron movement in the TFPV layers 20, 24, which results in corresponding increase in the current generated by the solar modules 10 and 11.

If quantum dots 30 are used, each of the TFPV layers 20, 24 may have up to approximately 10 to 12 photoactive layers 28 before the light penetration to the lower layers (away from the light 42) reduces to a level which is no longer useful in generating current. The TFPV layers 20, 24 made of CdTe/CdS or CIGS photoactive layers 28 may have up to approximately 5 or 6 layers before the level of light penetration becomes no longer useful.

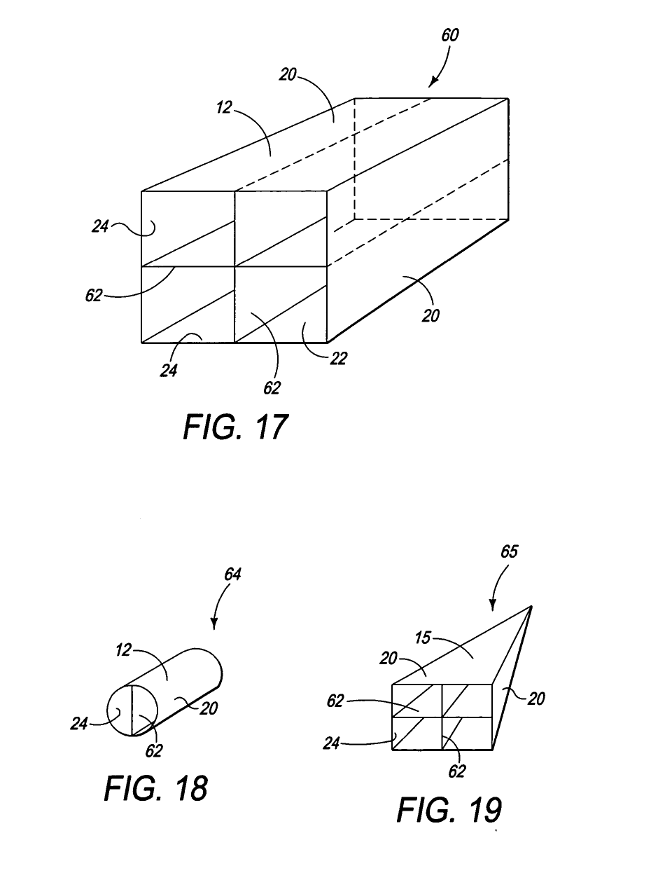

FIG. 17 shows another embodiment, wherein the present solar module, generally designated 60, is provided with at least one insert panel 62 (two shown in FIG. 17) that extends substantially through the entire length of the solar module. The insert panels 62 have substantially the same construction as the double-sided TFPV layers 20, 24 described above, with the photoactive layers 28 facing in the opposite directions. They are also fabricated in the same manner as the TFPV panels 20, 24.

In the module 60, two insert panels 62 are interlocked together and secured to the inside wall 22 of the tubular body 12 in any suitable manner. For example, if the insert panels 62 are attached to the frame 30 in the manner described above to form the structure shown in FIG. 15, the body 12 of the solar module 60 may include integrally formed surfaces for supporting or forming the two insert panels 62.

Alternatively, the insert panels 62 may be fabricated incorporating the frame 30, and the double-sided tubular body 12 is formed without a frame, around the insert panels. For some use, this may be sufficient to keep the insert panels 62 in the tubular body 12, without additional support. For other applications, insert panels 62 may need to be secured to the inside wall 22 of the tubular body 12 in some manner, for example, using adhesive.

Referring now to FIGS. 18 and 19, other examples of the present solar module, generally designated 64 and 65, respectively, are shown provided with the insert panel 62. Shared components with the modules 10, 11 and 60 are designated with identical reference numbers. The main difference between the modules 60 and 64 is that in module 64 the tubular body 12 is circular in cross-section rather than square or rectangular, and between the modules 60 and 65, module 65 has a conical body 15 rather than tubular. The tubular and conical bodies 12 and 15 of the modules 64 and 65 may also have other cross-sections such as oval or polygonal shapes such as those shown in FIGS. 2-6 and 8-12. While only a single insert panel 62 is shown in FIGS. 18 and 19, intersecting panels as depicted in FIG. 17 are also contemplated.

It will be appreciated that the insert panels 62 add more surface area for receiving light from the source. Each insert panel 62 adds approximately 50% more collection area than the tubular and conical configurations alone. With less visible, UV and IR spectrum light 42 reaching inside the tubular configuration of the solar modules 10, 11, 60, 64, 65 and with the insert panels 62 in place, there is an additional loss of efficiency per square meter of TFPV panels used in the overall design. However, the offset of up to 20% loss of efficiency per square meter of TFPV panel used is more than made up for in terms of adding approximately 50% more light collection area. The net gain per square meter is nearly 60% more power output. This additional power output per square meter further enhances the smaller footprint advantage of the present tubular configuration vs. traditional planar solar options. The reduced efficiency of the average solar cell used in the insert panels 62 and the tubular and conical configurations is more than made up for in the total watts of output generated.

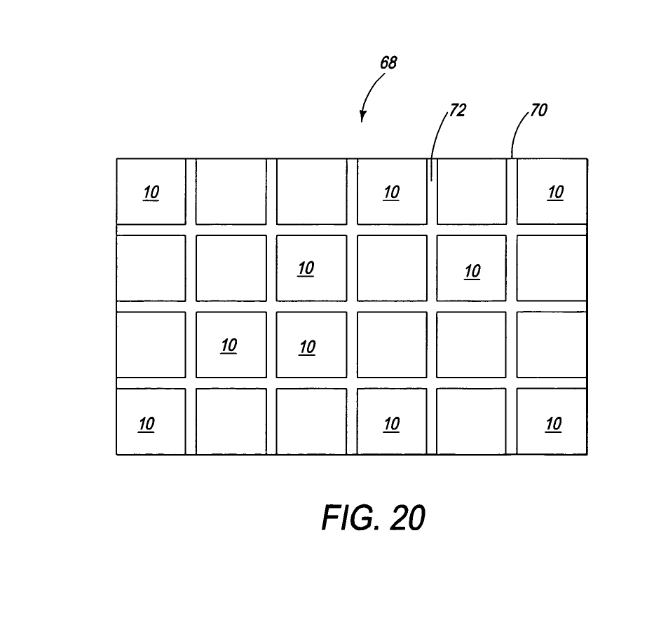

Turning now to FIG. 20, an array or solar unit 68 is formed using a plurality of solar modules 10 or solar modules having any other tubular body 12 or conical body 15 shapes. The solar unit 68 includes a base 70 formed from a suitably stiff plastic or composite material or other environmentally resistant material such as wood, aluminum, steel or the like. The solar modules 10 are attached to an upper surface 72 of the base 70 at one of the openings 14 or 16 using adhesives, clamps, clips or other suitable fasteners. The solar unit 68 may also be a preformed solid unit with the frame 30 (best shown in FIG. 15) of the solar modules 10 integrally formed with the base 72.

The solar modules 10 are preferably spaced from each other to allow light to reach all the surfaces of the outside TFPV panels 20, or are placed in contact with adjacent modules to reduce unused area of the base 70. In the latter case, only the solar modules 10 at the outermost or periphery of the array, and only the sides of these outermost cell modules that face away from the center of the solar unit, would be provided with the outside TFPV panel 20.

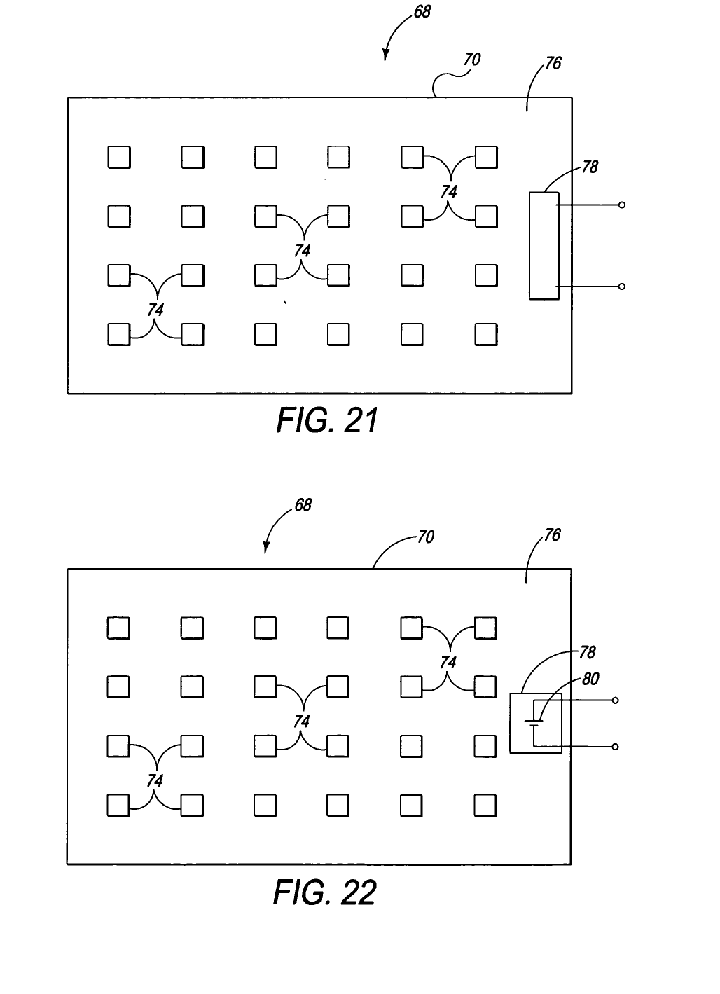

Referring now to FIG. 21, a plurality of inverters 74, each corresponding to a solar module 10, is provided on a bottom surface 76 of the base 70. Each inverter 74 is electrically connected to its corresponding cell module 10 through wires (not shown) preferably extending through the base 70. The inverters 74 convert DC power generated by the solar modules 10 into AC power. The inverters 74 are individually connected by wires (not shown) to a connection terminal 78 that transmits the power converted by the inverters at a specific frequency to minimize loss and reduce conductor size over long distances. The AC power from the inverters 74 is rectified back to DC power and applied to a certified industrial grade inverter where the power is once again inverted to AC and fed back into the grid

In another embodiment, power from the inverters 74 is rectified back to DC at the connection terminal 76 and is sunk into at least one battery module 80 in a series, parallel or series parallel connection where the stored energy may be inverted back to AC power in a form usable to a power utility. This arrangement allows the solar unit 70 to keep functioning even when any solar modules 10 stop performing. The battery module 80 may be a lithium ion battery that is screen printed directly on the surface 76 of the base 70, or any other type of battery that may be attached to the base directly, or remotely located. It will be appreciated that with the extended advantages of more reliable output per day using the UV, IR and visible light spectra by the solar modules 10, it is expected that less battery support will be required than typically used for solar support to achieve the same power backup.

While various embodiments of the present solar module have been shown and described, it should be understood that other modifications, substitutions and alternatives are apparent to one of ordinary skill in the art. Such modifications, substitutions and alternatives can be made without departing from the spirit and scope of the invention, which should be determined from the appended claims.

Various features of the module are set forth in the appended claims.

What is claimed is:

1. A solar module for converting light into electric current, comprising:
a hollow body having a first opening for enabling light to enter said hollow body, an inside wall and an outside wall;
at least one first photoactive layer for absorbing light attached to said inside wall and said outside wall of said body and for converting absorbed light into electric current.

2. The solar module as defined in claim 1, further comprising a second opening opposite said first opening.

3. The solar module as defined in claim 2, wherein said body comprises a generally tubular shape.

4. The solar module as defined in claim 2, wherein said first and second openings are oval or circular.

5. The solar module as defined in claim 2, wherein first and second openings have a polygonal shape.

6. The solar module as defined in claim 1, further comprising an enclosed end opposite said first opening.

7. The solar module as defined in claim 6, wherein body comprises a generally conical shape.

8. The solar module as defined in claim 6, wherein said first opening is generally oval or circular.

9. The solar module as defined in claim 6, wherein said first opening comprises a polygonal shape.

10. The solar module as defined in claim 1, wherein said first photoactive layer is formed on a flexible first substrate and said second photoactive layer is formed on a second flexible substrate.

11. The solar module as defined in claim 10, wherein said first substrate forms said inside wall of said body and said second substrate forms said outside wall of said body.

12. The solar module as defined in claim 11, wherein said first and second substrates are attached together to form said body.

13. The solar module as defined in claim 10, wherein said first substrate is attached to said inside wall of said body and said second substrate is attached to said outside wall of said body.

14. The solar module as defined in claim 13, wherein said body is formed from a plastic material.

15. The solar module as defined in claim 1, wherein said first and second photoactive layers are formed from at least one thin film photovoltaic (TFPV) layer.

16. The solar module as defined in claim 15, wherein said TFPV layer includes at least one layer of CdTe or CIGS.

17. The solar module as defined in claim 15, wherein said TFPV layer includes at least one layer of IR light absorbing quantum dots, at least one layer of visible light absorbing quantum dots and at least one layer of UV light absorbing quantum dots.

18. The solar module as defined in claim 1, further comprising at least one insert panel provided inside said hollow body and extending substantially from said first opening to an opposite end of said body, said insert panel having a photoactive layer s for absorbing light attached on opposite sides of said insert panel.

19. The solar module as defined in claim 1, further comprising an electrically conductive film disposed on both sides of said first photoactive layer for conducting current generated by said first photoactive layer, and on both sides of said second photoactive layer for conducting current generated by said second photoactive layer.

20. A solar unit for generating electric power from light, comprising:
a base having a first side and a second side opposite said first side;
an array of solar modules arranged on said first side of said base;
said solar modules each having a hollow body, a first opening at a first end of said body, a second end opposite said first opening attached to said first side of said base, an inside wall and an outside wall; and
at least one first photoactive layer for absorbing and converting light into current, attached to said inside wall of said body of each said solar modules, and at least one second photoactive layer for absorbing and converting light into current, attached to said outside wall of said body of at least said solar modules that are provided on a periphery of said array;
wherein current generated in said solar modules is output by said solar unit to generate electric power.

21. The solar unit as defined in claim 20 further comprising at least one inverter provided on said second side of said base for converting DC power from said solar module to AC power.

22. The solar unit as defined in claim 21, wherein said inverters are electrically connected to an output terminal provided on said second side of said base.

23. The solar unit as defined in claim 21 further comprising a battery provided on said second side of said base and electrically connected to said inverter for storing electric power from said solar modules.

24. A solar module for generating electric current, comprising:
a hollow body having a first opening for enabling light to enter said hollow body, an inside wall and an outside wall;
a thin film photovoltaic panel for absorbing light attached to said inside wall and said outside wall of said body;
wherein said thin film photovoltaic panels on said inside and outside walls generate current from at least one of IR light, visible light and UV light.
